(19) United States
(12) Patent Application Publication
(10) Pub. No.: US 2009/0127604 A1
(43) Pub. Date: May 21, 2009

(54) FERROELECTRIC MEMORY DEVICE AND METHOD FOR MANUFACTURING THE SAME

(75) Inventor: Takafumi NODA, Matsumoto (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/270,321

(22) Filed: Nov. 13, 2008

(30) Foreign Application Priority Data
Nov. 20, 2007 (JP) 2007-300566

(51) Int. Cl. H01L 29/92; H01L 21/02

(52) U.S. Cl. 257/295; 438/3; 257/E29.342; 257/E21.008

(57) ABSTRACT

A ferroelectric memory device includes: a substrate; a ferroelectric capacitor forming above the substrate, and having a lower electrode layer, a ferroelectric layer and an upper electrode layer; a first hydrogen barrier layer that covers the ferroelectric capacitor; an interlayer dielectric layer formed above the first hydrogen barrier layer; and a contact section that penetrates the interlayer dielectric layer and the first hydrogen barrier layer and connects to the upper electrode layer, wherein the contact section includes a first barrier layer in contact with the upper electrode layer, a second hydrogen barrier layer formed above the first barrier layer and a plug layer formed above the second hydrogen barrier layer.

The entire disclosure of Japanese Patent Application No. 2007-300566, filed Nov. 20, 2008 is expressly incorporated by reference herein.

### BACKGROUND

1. Technical Field

The present invention relates to ferroelectric memory devices and methods for manufacturing the same.

2. Related Art

It is important to prevent the characteristics of ferroelectric capacitors from deteriorating in the process for manufacturing ferroelectric memory devices. It is known that the characteristics of ferroelectric capacitors deteriorate when they contact with reducing substance, such as, hydrogen, water and the like. Therefore, ferroelectric capacitors are generally covered by hydrogen barrier layers.

In order to secure electrical conductivity, a portion of the hydrogen barrier layer is removed in a region where the upper electrode layer of a ferroelectric capacitor and a contact section contact each other. For this reason, during the step of fabricating the contact section, and in later steps, deteriorating factors such as hydrogen may penetrate the ferroelectric capacitor through the contact section, which would likely cause deterioration of the characteristics of the ferroelectric capacitor.

It is therefore important to prevent penetration of deteriorating factors such as hydrogen into ferroelectric capacitors through contact sections in order to prevent deterioration of the characteristics of ferroelectric capacitors during the manufacturing process. For example, Japanese Laid-open Patent Application JP-A-2006-222389 describes a technique to address the aforementioned problem.

### SUMMARY

In accordance with an advantage of some aspects of the present invention, it is possible to provide ferroelectric memory devices in which deterioration of the characteristics of ferroelectric capacitors can be prevented during the manufacturing process, and it is also possible to provide a method for manufacturing such ferroelectric memory devices.

A ferroelectric memory device in accordance with an embodiment of the invention includes: a substrate; a ferroelectric capacitor forming above the substrate, and having a lower electrode layer, a ferroelectric layer and an upper electrode layer; a first hydrogen barrier layer that covers the ferroelectric capacitor; an interlayer dielectric layer formed above the first hydrogen barrier layer; and a contact section that penetrates the interlayer dielectric layer and the first hydrogen barrier layer and connects to the upper electrode layer, wherein the contact section includes a first barrier layer in contact with the upper electrode layer, a second hydrogen barrier layer formed above the first barrier layer and a plug layer formed above the second hydrogen barrier layer.

The ferroelectric memory device in accordance with the present embodiment has the second hydrogen barrier layer at the contact section, whereby deterioration of the characteristics of the ferroelectric capacitor can be prevented during the manufacturing steps.

In the description of the invention, the term “above” is used, for example, as in a statement “a specific component (hereinafter called ‘B’) is formed “above” another specific component (hereinafter called ‘A’).” In such a case, the term “above” is used in the description of the invention, while assuming to include the case where the component B is formed directly on the component A and the case where the component B is formed over the component A through another component provided on the component A.

In the ferroelectric memory device in accordance with an aspect of the embodiment of the invention, the contact section may have a second barrier layer between the second hydrogen barrier layer and the plug layer.

In the ferroelectric memory device in accordance with an aspect of the embodiment of the invention, the second hydrogen barrier layer may be composed of a dielectric material.

A method for manufacturing a ferroelectric memory device in accordance with an embodiment of the invention includes the steps of: forming, above a substrate, a ferroelectric capacitor having a lower electrode layer, a ferroelectric layer and an upper electrode layer; forming a first hydrogen barrier layer that covers the ferroelectric capacitor; forming an interlayer dielectric layer above the first hydrogen barrier layer; etching the interlayer dielectric layer and the first hydrogen barrier layer to form a contact hole that reaches the upper electrode layer; forming a first barrier layer in the contact hole in contact with the upper electrode layer; forming a second hydrogen barrier layer above the first barrier layer; and forming a plug layer above the second hydrogen barrier layer.

### BRIEF DESCRIPTION OF THE DRAWINGS

FIG. 1 is a schematic cross-sectional view of a ferroelectric memory device in accordance with an embodiment of the invention.

FIG. 2 is a schematic cross-sectional view showing a manufacturing step for manufacturing a ferroelectric memory device in accordance with an embodiment of the invention.

FIG. 3 is a schematic cross-sectional view showing a manufacturing step for manufacturing the ferroelectric memory device in accordance with the present embodiment.

FIG. 4 is a schematic cross-sectional view showing a manufacturing step for manufacturing the ferroelectric memory device in accordance with the present embodiment.

FIG. 5 is a schematic cross-sectional view showing a manufacturing step for manufacturing the ferroelectric memory device in accordance with the present embodiment.

FIG. 6 is a schematic cross-sectional view showing a manufacturing step for manufacturing the ferroelectric memory device in accordance with the present embodiment.

### DESCRIPTION OF EXEMPLARY EMBODIMENTS

Preferred embodiments of the invention are described below with reference to the accompanying drawings.

1. Ferroelectric Memory Device

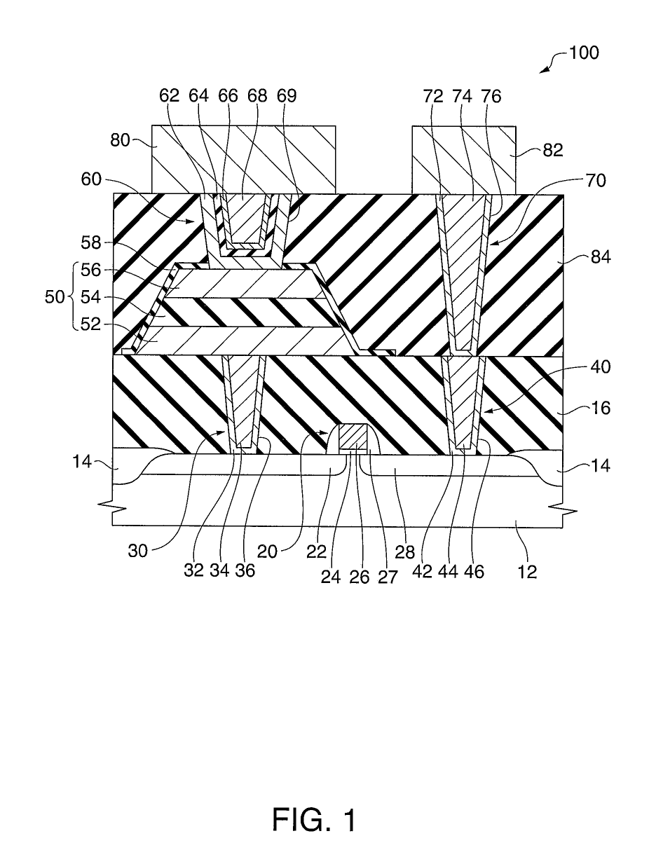

FIG. 1 is a schematic cross-sectional view of a ferroelectric memory device 100 in accordance with an embodiment of the invention.

The ferroelectric memory device 100 in accordance with the present embodiment includes a substrate 12, a ferroelectric capacitor 50 and a contact section 60.

For example, a single crystal silicon substrate can be used as the substrate 12.

Element isolation regions 14 are formed in the substrate 12. The element isolation regions 14 function to electrically insulate and separate one area from another in the substrate 12.

A transistor 20 is formed in a region defined by the element isolation regions 14. The transistor 20 includes first and second impurity regions 22 and 28 each forming a source or a drain, a gate dielectric film 24, a gate 26 on the gate dielectric film, and a side wall dielectric layer 27. A first interlayer dielectric layer 16 is formed on the transistor 20. A contact section 30 is formed on the first impurity region 22. A contact section 40 is formed on the second impurity region 28.

The ferroelectric capacitor 50 is formed on the contact section 30. The ferroelectric capacitor 50 includes a lower electrode layer 52, a ferroelectric layer 54 and an upper electrode layer 56.

The material for the lower electrode layer 52 may be, for example, at least one material selected from platinum, ruthenium, iridium and oxides of the foregoing materials. Also, the lower electrode layer 52 may be in a single layer or a multilayer of laminated films of the foregoing exemplified materials.

The ferroelectric layer 54 may be composed of complex oxide. The complex oxide may have a perovskite type crystal structure. As the complex oxide, Pb(Zr,Ti) O₃ (PZT) may be a representative material, and this basic composition may further include a small amount of additive elements. Also, as the complex oxide, SrBi₂Ta₂O₉ (SBT), (Bi, La)₄Ti₃O₁₂ (BLT), or Pb (Zr_{1-x-y}, Tiₓ) Nb_{y} O₃ (PZTN) (0.0<x≦0.5, 0.0<y≦0.2), having a perovskite type crystal structure may be used.

As the material for the upper electrode layer 56, for example, at least one of platinum, ruthenium, iridium and oxides of the aforementioned materials may be used. Also, the upper electrode layer 56 may be in a single layer or a multilayer of laminated films of the foregoing exemplified materials.

The first hydrogen barrier layer 58 may be formed in a manner to cover at least the ferroelectric capacitor 50. The first hydrogen barrier layer 58 may be formed from a dielectric material having a high hydrogen barrier capability, such as, for example, aluminum oxide, silicon nitride, or the like. The first hydrogen barrier layer 58 is provided, in particular, to prevent the ferroelectric capacitor 50 from contacting substances having reducing property such as hydrogen, water and the like.

A second interlayer dielectric layer 84 is formed on the first interlayer dielectric layer 16 and the first hydrogen barrier layer 58. As the material for the second interlayer dielectric layer 84, any material having dielectric property may be used. As the material for the second interlayer dielectric layer 84, for example, at least one of silicon oxide, silicon nitride and silicon oxinitride may be used. The second interlayer dielectric layer 84 may be in a single layer or a multilayer. Contact sections 60 and 70 are formed in the second dielectric layer 84.

The contact section 60 is formed on the ferroelectric capacitor 50. The contact section 60 has a first barrier layer 62, a second hydrogen barrier layer 64, a second barrier layer 66 and a plug layer 68. The contact section 60 penetrates the second interlayer dielectric layer 84 and the first hydrogen barrier layer 58 and connects to the upper electrode layer 56. In other words, the contact section 60 electrically connects the ferroelectric capacitor 50 with a wiring 80.

The first barrier layer 62 is formed along an inner wall of a contact hole 69 and a top surface of the upper electrode layer 56. The material for the first barrier layer 62 may be, for example, at least one of titanium aluminum nitride and titanium nitride. The first barrier layer 62 functions to prevent the ferroelectric capacitor 50 from contacting substances having reducing property such as hydrogen, water and the like. Furthermore, the first barrier layer 62 functions to prevent the substance composing the plug layer 68 from diffusing into the second interlayer dielectric layer 84 and the upper electrode layer 56.

The second hydrogen barrier layer 64 is formed on the first barrier layer 62. The second hydrogen barrier layer 64 is formed from a material having higher hydrogen barrier capability, compared to the first barrier layer 62. As the material for the second hydrogen barrier layer 64, a dielectric material having high hydrogen barrier capability, such as, for example, aluminum oxide, silicon nitride, or the like may be used. The second hydrogen barrier layer 64 functions to prevent the ferroelectric capacitor 50 from contacting substances having reducing property, such as, hydrogen, water and the like.

The second barrier layer 66 is formed on the second hydrogen barrier layer 64. The material for the second barrier layer 66 may be, for example, at least one of titanium aluminum nitride and titanium nitride, like the first barrier layer 62. In accordance with the present embodiment, the second barrier layer 66 may not need to be formed, because sufficient hydrogen barrier property is secured by the first barrier layer 62 and the second hydrogen barrier layer 64.

The contact section 60 maintains its electrical conductivity by the first barrier layer 62, as the second hydrogen barrier layer 64 is dielectric. The first barrier layer 62 may be formed in a greater film thickness as it is necessary to provide electrical conductivity, compared with the second barrier layer 66 that hardly contributes to electrical conductivity.

The plug layer 68 is formed inside the contact hole 69 that is surrounded by the second barrier layer 66. The material for the plug layer 68 may be metal, for example, tungsten, copper and the like.

In the step of forming the plug layer 68, hydrogen generally exists. In this step, for example, if the contact section 60 had not the second hydrogen barrier layer 64, it would be difficult to perfectly prevent penetration of hydrogen into the region where the ferroelectric capacitor 50 is formed, as the first barrier layer 62 and the second barrier layer 66 have relatively lower hydrogen barrier capability. In the ferroelectric memory device 100 in accordance with the present embodiment, the contact section 60 has the second hydrogen barrier layer 64 that uses a dielectric material having high hydrogen barrier capability, such that penetration of hydrogen into the region where the ferroelectric capacitor 50 is formed can be securely prevented. Accordingly, in the ferroelectric memory device 100 in accordance with the present embodiment, deterioration of the characteristics of the ferroelectric capacitor 50 can be suppressed during the process of forming the plug layer 68.

The second hydrogen barrier layer 64 may be formed from a dielectric material. For this reason, the second barrier layer 66 and the plug layer 68 hardly contribute to electrical conduction. Accordingly, the contact section 60 achieves electrical conduction mainly by the first barrier layer 62. The contact section 60 needs only to apply a voltage to the ferroelectric capacitor 50, and therefore is applicable to a ferroelectric memory device.

The contact section 70 is formed on the contact section 40. The contact section 70 has a barrier layer 72 and a plug layer 74. The material for the barrier layer 72 may be at least one of titanium aluminum nitride and titanium nitride. As the material for the plug layer 74, metal, such as, for example, tungsten, copper and the like may be used.

A wiring 80 is formed on the contact section 60. A wiring 82 is formed on the contact section 70. As the material for the wirings 80 and 82, for example, aluminum or the like may be used.

The ferroelectric memory device 100 in accordance with the present embodiment has, for example, the following characteristics.

In the ferroelectric memory device 100 in accordance with the present embodiment, areas of the ferroelectric capacitor 50 that may be in contact with the second interlayer dielectric layer 84 are covered by the first hydrogen barrier layer 58. Furthermore, at the contact section 60, the second hydrogen barrier layer 64 is formed along the inner wall of the contact hole 69 and the top surface of the upper electrode layer 56 through the first barrier layer 62. Therefore, by the ferroelectric memory device 100 in accordance with the present embodiment, the ferroelectric capacitor 50 can securely prevent penetration of deteriorating factors from the second interlayer dielectric layer 84 as well as penetration of deteriorating factors through the contact section 60. Therefore, because of the provision of the first hydrogen barrier layer 58 and the second hydrogen barrier layer 64, the ferroelectric memory device 100 in accordance with the present embodiment exhibits high hydrogen barrier capability and can prevent deterioration of the characteristics of the ferroelectric capacitor 50 during the manufacturing process.

2. Method for Manufacturing Ferroelectric Memory Device

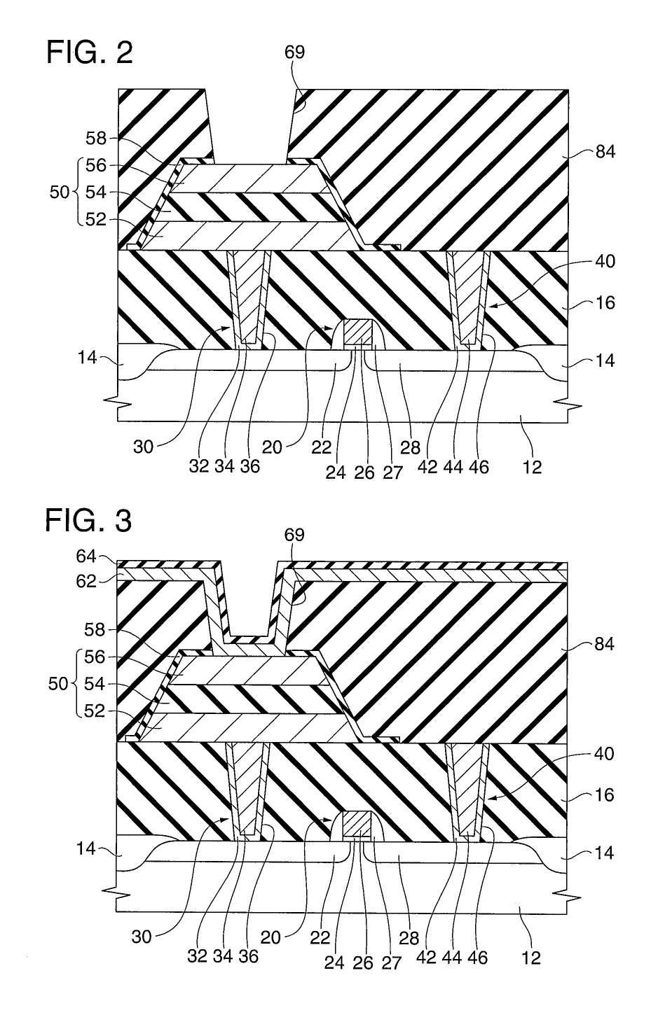

Next, a method for manufacturing the ferroelectric memory device 100 in accordance with an embodiment of the invention is described with reference to the accompanying drawings. FIGS. 2-6 are schematic cross-sectional views showing a process for manufacturing the ferroelectric memory device 100 in accordance with the present embodiment.

As shown in FIG. 2, element isolation regions 14 and transistors 20 are formed in a substrate 12. The element isolation regions 14 and the transistors 20 may be formed by a known technology.

Next, a first interlayer dielectric layer 16 is formed on the transistors 20. The first interlayer dielectric layer 16 may be formed by a known technique.

Next, contact sections 30 and 40 are formed. The contact sections 30 and 40 may be formed by a known technique. For example, contact holes 36 and 46 are formed in the first interlayer dielectric layer 16 by dry etching, and then barrier layers 32 and 42 and plug layers 34 and 44 are embedded in the contact holes 36 and 46 by a sputter method or a chemical vapor deposition (CVD) method. Then, the barrier layers 32 and 42 and the plug layers 34 and 44 on the first interlayer dielectric layer 16 are removed by a chemical mechanical polishing (CMP) method, whereby the contact sections 30 and 40 are formed.

Next, a ferroelectric capacitor 50 is formed on the contact section 30 and the first interlayer dielectric layer 16. First, a lower electrode layer 52, a ferroelectric layer 54 and an upper electrode layer 56 are sequentially laminated on the contact section 30 and the first interlayer dielectric layer 16. The lower electrode layer 52 and the upper electrode layer 56 may be formed by, for example, a sputter method or a vapor deposition method. The ferroelectric layer 54 may be formed by, for example, a sol-gel method, a chemical vapor deposition (CVD) method, a metal organic decomposition (MOD) method, or a sputter method. Then, the lower electrode layer 52, the ferroelectric layer 54 and the upper electrode layer 56 are patterned in a predetermined shape. As a result, the ferroelectric capacitor 50 is formed.

Next, a first hydrogen barrier layer 58 is formed on the ferroelectric capacitor 50. The first hydrogen barrier layer 58 may be formed by, for example, a sputter method or a chemical vapor deposition (CVD) method. Then, the first hydrogen barrier layer 58 is patterned in a manner to cover at least the ferroelectric capacitor 50.

Then, a second interlayer dielectric layer 84 is formed on the first hydrogen barrier layer 58 and the first interlayer dielectric layer 16. The second interlayer dielectric layer 84 may be formed by a known technique, such as, a chemical vapor deposition (CVD) method, a spin coat method or the like. The second interlayer dielectric layer 84 may be subject to a chemical mechanical polishing (CMP) method or the like, thereby planarizing the top surface of the second interlayer dielectric layer 84.

Next, a contact hole 69 is formed on the ferroelectric capacitor 50. The contact hole 69 may be formed by, for example, photolithography. The contact hole 69 may be formed in a manner to penetrate the second interlayer dielectric layer 84 and the first hydrogen barrier layer 58, and expose the upper electrode layer 56.

Next, as shown in FIG. 3, a first barrier layer 62 and a second hydrogen barrier layer 64 are sequentially laminated on the second interlayer dielectric layer 84, on the inner wall of the contact hole (side walls of the second interlayer dielectric layer 84 and the first hydrogen barrier layer 58) and on the bottom section of the contact hole 69 (top surface of the upper electrode layer 56). The first barrier layer 62 may be formed by, for example, a sputter method. The film thickness of the first barrier layer 62 may be, for example, 50-200 nm. The second hydrogen barrier layer 64 may be formed by, for example, an atomic layer chemical vapor deposition (ALCVD) method. The film thickness of the second hydrogen barrier layer 64 may be, for example, 5-20 nm when aluminum oxide is used, and 5-50 nm when silicon nitride is used. The atomic layer chemical vapor deposition (ALCVD) method has excellent embedding property, compared to sputter methods, and therefore can accommodate miniaturization.

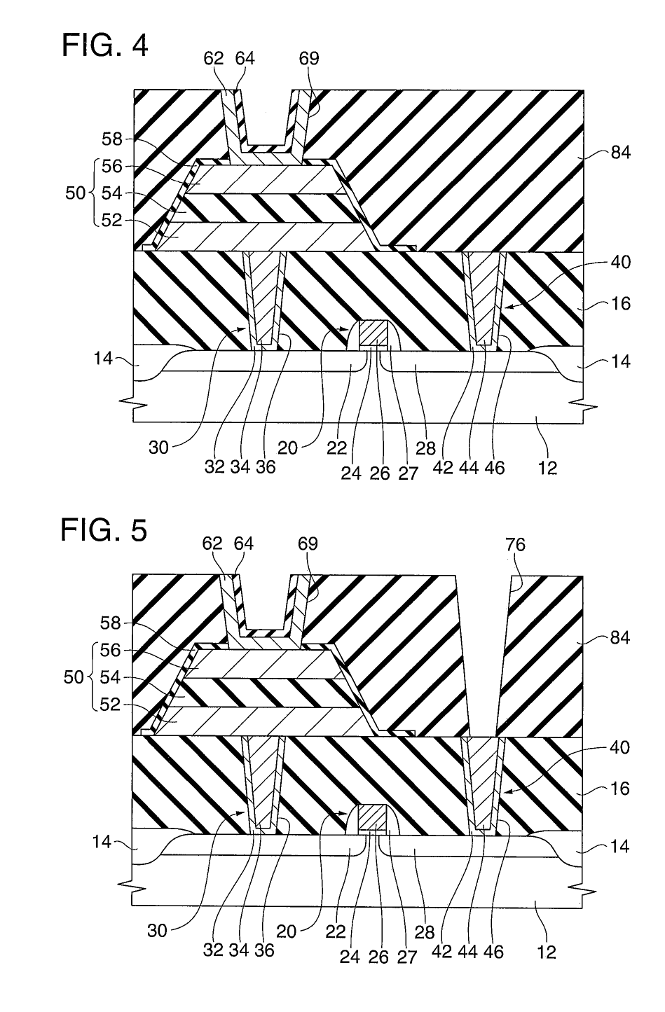

Next, as shown in FIG. 4, the first barrier layer 62 and the second hydrogen barrier layer 64 on the second interlayer dielectric layer 84 are removed. The first barrier layer 62 and the second hydrogen barrier layer 64 are removed until the second interlayer dielectric layer 84 is exposed. The first barrier layer 62 and the second hydrogen barrier layer 64 may be removed by, for example, a chemical mechanical polishing (CMP) method, an etch-back method, or the like.

Next, as shown in FIG. 5, a contact hole 76 is formed on the contact section 40. The contact hole 76 may be formed by, for example, photolithography. More specifically, for example, a resist layer (not shown) having an opening in a portion of the second interlayer dielectric layer 84 is formed, and then dry etching is conducted at the opening area in the resist layer, thereby forming the contact hole 76.

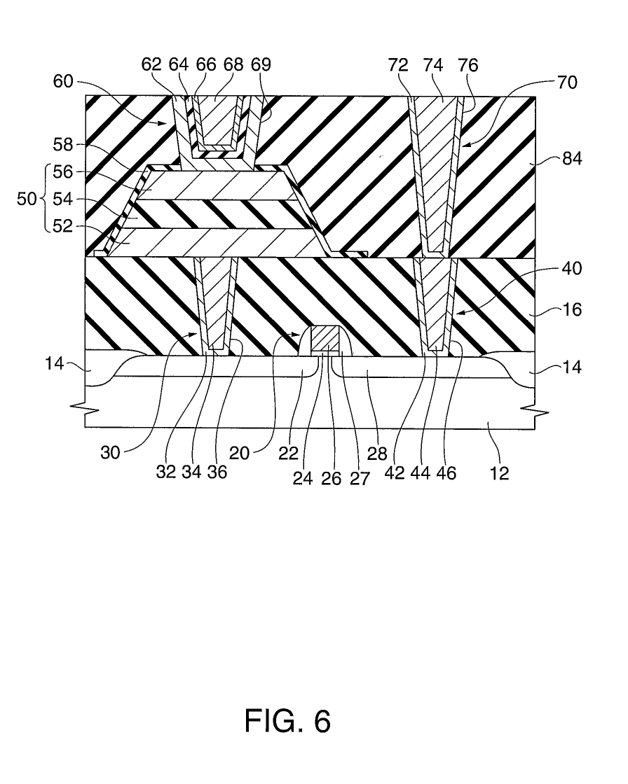

Next, as shown in FIG. 6, a second barrier layer 66 and a plug layer 68 are formed on the second hydrogen barrier layer 64, and a barrier layer 72 and a plug layer 74 are formed in the contact hole 76. More specifically, first, a layer that becomes to be the second barrier layer 66 and the barrier layer 72 is formed on the second interlayer dielectric layer 84, on the second hydrogen barrier layer 64 and on the inner side of the contact hole 76. The layer that becomes to be the second barrier layer 66 and the barrier layer 72 may be formed by, for example, a sputter method. Next, the plug layers 68 and 74 are formed on the layer that becomes to be the second barrier layer 66 and the barrier layer 72. The plug layers 68 and 74 may be formed by, for example, a chemical vapor deposition (CVD) method. For example, tungsten hexafluoride (WF₆) and hydrogen (H₂) or tungsten hexafluoride (WF₆) and silane (SiH₄) may be thermally reacted, thereby depositing tungsten. Then, the layer that becomes to be the second barrier layer 66 and the barrier layer 72 on the second interlayer dielectric layer 84 and the plug layers 68 and 74 are removed until the second interlayer dielectric layer 84 is exposed. The removal step may be conducted by, for example, a chemical mechanical polishing (CMP) method, or an etch-back method.

Next, as shown in FIG. 1, wirings 80 and 82 are formed. The wiring layers 80 and 82 may be formed by, for example, a sputter method. The wiring layers 80 and 82 may be patterned by a known method in desired areas.

By the steps described above, the ferroelectric memory device 100 in accordance with the present embodiment is fabricated, as shown in FIG. 1.

The method for manufacturing a ferroelectric memory device 100 in accordance with the present embodiment has, for example, the following characteristics.

According to the method for manufacturing a ferroelectric memory device 100 in accordance with the present embodiment, the contact section 60 has the second hydrogen barrier layer 64, such that hydrogen present in the step of forming the plug layer 68 can be securely prevented from penetrating the ferroelectric capacitor 50. Therefore, in accordance with the present embodiment, deterioration of the characteristics of the ferroelectric capacitor 50 during its manufacturing process can be suppressed.

For example, if the contact section 60 had not the second hydrogen barrier layer 64, high level controls would be required for forming the contact hole 69 and the first barrier layer 62 because the hydrogen barrier property of the first barrier layer 62 needs to be increased. According to the method for manufacturing a ferroelectric memory device 100 in accordance with the present embodiment, the second hydrogen barrier layer 64 having high hydrogen barrier capability is provided, whereby the manufacturing margin can be increased without requiring high level control in forming the contact hole 69 and the first barrier layer 62.

Preferred embodiments of the invention are described above, but the invention is not limited to those embodiments. For example, in the examples described above, the material for the second hydrogen barrier layer 64 is a dielectric material. However, a conductive material having hydrogen barrier property such as titanium aluminum and the like may be used instead. Also, for example, the contact section 70 may include a second hydrogen barrier layer 64 formed therein, like the contact section 60.

The embodiments of the invention are described above in detail. However, those skilled in the art should readily understand that many modifications can be made without departing in substance from the novel matter and effects of the invention. Accordingly, those modified examples are deemed to be included in the scope of the invention.

What is claimed is:

1. A ferroelectric memory device comprising:
a substrate;
a ferroelectric capacitor forming above the substrate, and having a lower electrode layer, a ferroelectric layer and an upper electrode layer;
a first hydrogen barrier layer that covers the ferroelectric capacitor;
an interlayer dielectric layer formed above the first hydrogen barrier layer; and
a contact section that penetrates the interlayer dielectric layer and the first hydrogen barrier layer and connects to the upper electrode layer,
wherein the contact section includes a first barrier layer in contact with the upper electrode layer, a second hydrogen barrier layer formed above the first barrier layer and a plug layer formed above the second hydrogen barrier layer.

2. A ferroelectric memory device according to claim 1, wherein the contact section has a second barrier layer between the second hydrogen barrier layer and the plug layer.

3. A ferroelectric memory device according to claim 1, wherein the second hydrogen barrier layer is composed of a dielectric material.

4. A method for manufacturing a ferroelectric memory, the method comprising the steps of:
forming, above a substrate, a ferroelectric capacitor having a lower electrode layer, a ferroelectric layer and an upper electrode layer;
forming a first hydrogen barrier layer that covers the ferroelectric capacitor;
forming an interlayer dielectric layer above the first hydrogen barrier layer;
etching the interlayer dielectric layer and the first hydrogen barrier layer to form a contact hole that reaches the upper electrode layer;
forming a first barrier layer in the contact hole in contact with the upper electrode layer;
forming a second hydrogen barrier layer above the first barrier layer; and
forming a plug layer above the second hydrogen barrier layer.
